(19) United States
(12) Patent Application Publication
(10) Pub. No.: US 2002/0146909 A1
(43) Pub. Date: Oct. 10, 2002

(54) Method of smoothing inter-metal dielectric layers in semiconductor devices

(76) Inventors: Yi-chuan Yang, Taipei Hsien (TW); Jason C.S. Chu, Taipei (TW)

Correspondence Address: BIRCH STEWART KOLASCH & BIRCH, PO BOX 747, FALLS CHURCH, VA, 22040-0747, US

(21) Appl. No.: 10/115,038

(22) Filed: Apr. 4, 2002

(30) Foreign Application Priority Data
Apr. 4, 2001 (TW) 90108143

(51) Int. Cl. H01L 21/461

(52) U.S. Cl. 438/724

(57) ABSTRACT

A method of smoothing an inter-metal dielectric layer in a semiconductor device for reducing formation of voids. The method comprises the steps of: providing a semiconductor substrate with metal lines formed thereon; forming a first dielectric layer on the surface of the semiconductor substrate, covering the metal lines; forming a pre-planarization layer, with high fluidity and good gap-fill capacity, on the first dielectric layer; forming a spin-on layer on the pre-planarization layer; etching back the spin-on layer until exposing the pre-planarization layer; and forming a second dielectric layer on the pre-planarization layer and the spin-on layer. Furthermore, an IMD structure fabricated via the method is also disclosed.

### BACKGROUND OF THE INVENTION

1. Field of the Invention

The present invention relates in general to a method of fabricating semiconductors. More specifically, it relates to a method of smoothing an inter-metal dielectric layer for reducing formation of voids in a semiconductor device.

2. Description of the Related Art

Integrated circuits (ICs) for driving a liquid crystal display (hereinafter is referred to as LCD) have far more bonding pads than that of general DRAMs. Therefore, only 0.5 μm (or above) technology is appropriate for fabricating LCD driving ICs. In the technology of 0.5 μm and above processes, PE-SiH₄ oxide layers which are formed via PECVD (Plasma Enhanced Chemical Vapor Deposition) by using SiH₄ as main reaction gas, generally serve as inter-metal dielectric layers (hereinafter is referred to as IMD layers) for isolating metal layers in semiconductor devices. However, PE-SiH₄ oxide layers have inherent weakness in carrying out planarization (i.e., poor effect on smoothness) and less process window, consequently resulting in metal bridging problems in semiconductor devices.

FIG. 1 shows, in a cross-sectional view, a conventional dielectric layer having a sandwich structure in a semiconductor device. In FIG. 1, two metal lines 11 are formed on a semiconductor substrate 10. A first PE-SiH₄ oxide layer 12, a spin-on glass (SOG) layer 13, and a second PE-SiH₄ oxide layer 14 are subsequently formed on the semiconductor substrate 10 to constitute an IMD layer 16. The SOG layer 13 is etched back first, and then the second PE-SiH₄ oxide layer 14 is formed thereon. The IMD layer 16 is supposed to isolate metal lines 11 and carry out planarization.

It is noted that, when forming the second PE-SiH₄ oxide layer 14, voids 15 easily appear therein as depicted in FIG. 1. Metal will remain in the voids 15, after completing subsequent metallization process. Therefore, metal bridging happens, disabling the semiconductor device.

O₃/TEOS oxide layers have better fluidity, however they are not appropriate for directly serving as IMD layers. The reason is that an O₃/TEOS oxide layer cannot easily adhere to an etched-back SOG layer, due to its surface selectivity to different materials. Thus, using O₃/TEOS oxide layers as IMD layers confronts the issue of insufficient and nonuniform thickness.

### SUMMARY OF THE INVENTION

Therefore, an object of the present invention is to provide a method of smoothing an inter-metal dielectric layer in semiconductor device. According to the method, a pre-planarization layer having high fluidity and good gap-fill capacity, is additionally formed to the conventional IMD layer of sandwich structure. The pre-planarization layer fills the unevenness of a bottom layer of the conventional IMD layer, improving smoothness, thereby reducing generation of voids in a top layer of the conventional IMD layer.

The present invention achieves the above-indicated objects by providing a method of smoothing an inter-metal dielectric layer in semiconductor device comprises the following steps.

First, a first dielectric layer is formed on the surface of a semiconductor substrate. The semiconductor substrate has metal lines formed thereon, and the first dielectric layer covers the metal lines.

Secondly, a pre-planarization layer with high fluidity and good gap-fill capacity is formed on the first dielectric layer.

Next, a spin-on glass layer is formed on the pre-planarization layer, and then etched back until exposing the pre-planarization layer.

Finally, a second dielectric layer is formed on the pre-planarization layer and the spin-on glass layer.

A structure of an inter-metal dielectric layer is also disclosed. The structure is applied to a semiconductor substrate with metal lines formed, capable of having smooth surface and reducing formation of voids. The IMD structure comprises: a first PE-SiH4 oxide layer disposed on the semiconductor substrate; an O₃/TEOS oxide layer disposed on the PE-SiH4 oxide layer; a spin-on glass layer disposed on the O₃/TEOS oxide layer; and a second PE-SiH4 oxide layer disposed on the spin-on glass layer.

### BRIEF DESCRIPTION OF THE DRAWINGS

The following detailed description, given by way of example and not intended to limit the invention solely to the embodiments described herein, will best be understood in conjunction with the accompanying drawings, in which;

FIG. 1 shows, in a cross-sectional view, a conventional dielectric layer having a sandwich structure in a semiconductor device.

FIGS. 2a to 2e show a process of smoothing an inter-metal dielectric layer in semiconductor device, in a cross-sectional view, according to an embodiment of the present invention.

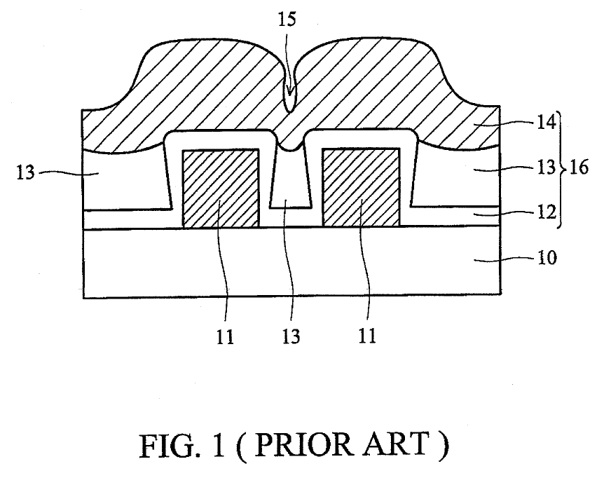

### DETAILED DESCRIPTION OF THE PREFERRED EMBODIMENTS

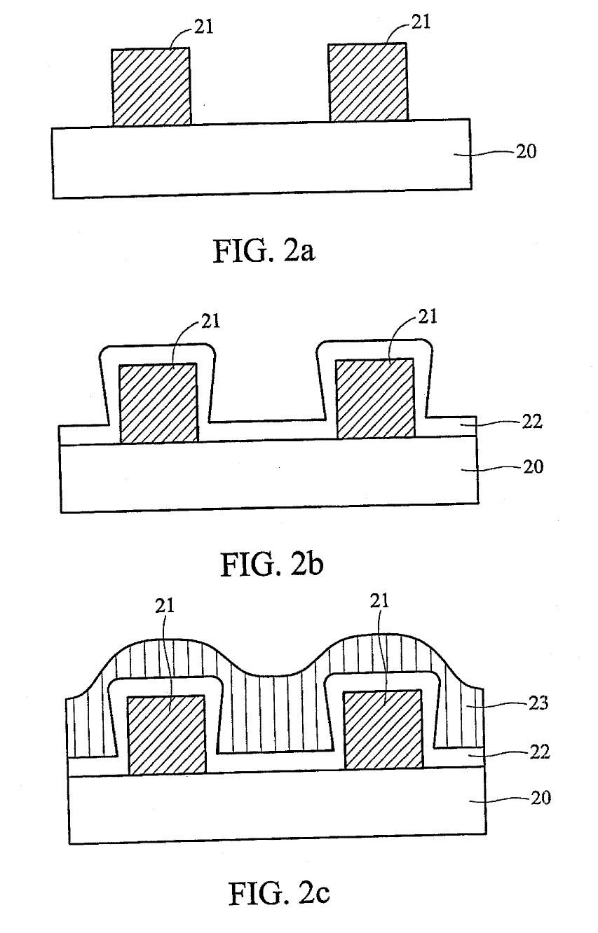

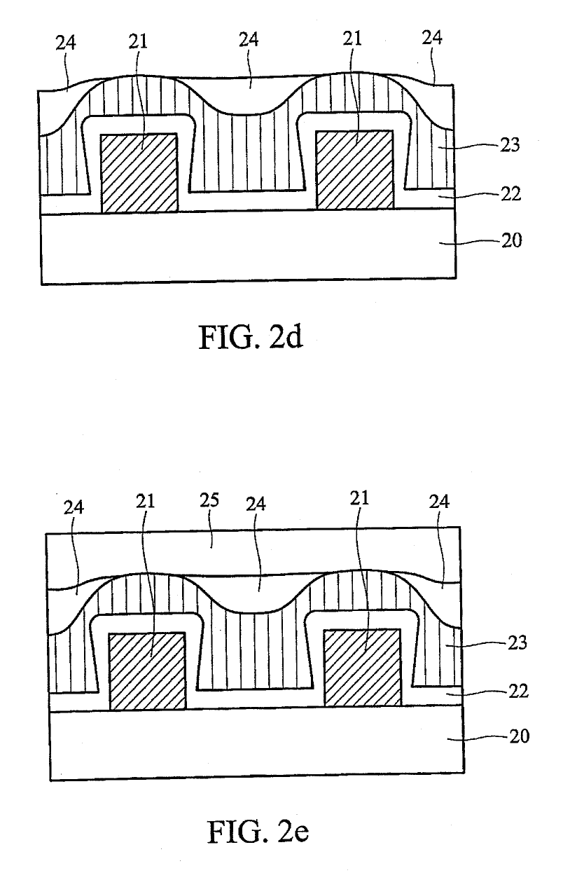

FIGS. 2a to 2e show a process of smoothing an IMD layer in semiconductor device, in cross-sectional view, according to an embodiment of the present invention.

First, a semiconductor substrate 20 with metal lines 21 formed thereon is provided, as depicted in FIG. 2a. Or a first metal layer has been fabricated on the semiconductor substrate 20.

Secondly, a first dielectric layer 22 is conformally formed on the semiconductor substrate 20, covering the metal lines 21, as depicted in FIG. 2b. The first dielectric layer 22 is an oxide layer fabricated via plasma enhanced vapor chemical deposition (PEVCD) method and using SiH₄ as main reacting gas in this embodiment. The oxide layer is named as PE-SiH₄ oxide layer.

Then, a pre-planarization layer 23 is formed on the dielectric layer 21, as depicted in FIG. 2c. The pre-planarization layer 23 is made from a material with high fluidity and good gap-fill capacity such as O₃/TEOS oxide compositions. Therefore, the unevenness or gap of the first dielectric layer 21 can be smoothed. The O₃/TEOS oxide has better gap-fill capacity and fluidity than PE-SiH₄, therefore improving the planarization.

Next, a spin-on glass (SOG) layer 24 is formed on the pre-planarization layer 23. Then, the SOG layer 24 is etched back until exposing the pre-planarization layer 23, as depicted in FIG. 2d.

Finally, a second dielectric layer 25 is formed on the pre-planarization layer 23 and the SOG layer 24, as depicted in FIG. 2e. In this embodiment, the second dielectric layer 25 is also a PE-SiH₄ oxide layer.

According to the above description, the present invention sequentially forms a PE-SiH₄ oxide layer, an O3/TEDS oxide layer, a SOG layer, and a PE-SiH4 oxide layer to obtain an IMD structure with better smooth surface.

The pre-planarization layer 23 (O₃/TEOS oxide layer) is provided between the first dielectric layer 22 (PE-SiH₄ oxide layer) and the SOG layer 24, thereby obtaining better planarization and preventing metal bridging problems in the following metallization process.

Furthermore, there is no selectivity issue between the interface of the pre-planarization layer 23 (O₃/TEOS layer) and the first dielectric layer 22 (PE-SiH₄ oxide layer), and thus their thickness will not be insufficient or nonuniform.

The method and IMD structure of the present invention can be applied to the latest semiconductor processes, also to the advanced semiconductor processes such as 0.35 um or below.

While the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of smoothing an inter-metal dielectric layer in a semiconductor device for reducing formation of voids, comprising the steps of:
providing a semiconductor substrate with metal lines formed thereon;
forming a first dielectric layer on the surface of the semiconductor substrate, covering the metal lines;
forming a pre-planarization layer, with high fluidity and good gap-fill capacity, on the first dielectric layer;
forming a spin-on glass layer on the pre-planarization layer;
etching back the spin-on glass layer until exposing the pre-planarization layer; and
forming a second dielectric layer on the pre-planarization layer and the spin-on glass layer.

2. The method as claimed in claim 1, wherein the pre-planarization layer is an O₃/TEOS oxide layer.

3. The method as claimed in claim 1, wherein the first and second dielectric layers are oxide layers formed via plasma enhanced chemical vapor deposition.

4. The method as claimed in claim 3, wherein the first and second dielectric layers are made by using SiH₄ as main reaction gas.

5. A structure of an inter-metal dielectric layer, applied in a semiconductor substrate with metal lines formed, capable of having smooth surface and reducing formation of voids, comprising:
a first PE-SiH4 oxide layer disposed on the semiconductor substrate;
an O₃/TEOS oxide layer disposed on the PE-SiH4 oxide layer;
a spin-on glass layer disposed on the O₃/TEOS oxide layer; and
a second PE-SiH₄ oxide layer disposed on the spin-on. glass layer.

6. The structure as claimed in claim 5, wherein the first and second PE-SiH₄ oxide layer are made via plasma enhanced chemical vapor deposition by using SiH₄ as main reaction gas.

7. The structure as claimed in claim 5, wherein the spin-on glass layer is etched back thereby exposing the O3/TEOS oxide layer.
